(19) United States
(12) Patent Application Publication
(10) Pub. No.: US 2026/0150529 A1
(43) Pub. Date: May 28, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-si (KR)

(72) Inventors: Jung Yun JO, Yongin-si (KR); Jin Gyu KIM, Yongin-si (KR)

(73) Assignee: Samsung Display Co., Ltd., Yongin-si (KR)

(21) Appl. No.: 19/333,972

(22) Filed: Sep. 19, 2025

(30) Foreign Application Priority Data
Nov. 22, 2024 (KR) 10-2024-0168485

(51) Int. Cl. H10K 59/124; H10K 59/12; H10K 59/121

(52) U.S. Cl. CPC H10K 59/124; H10K 59/1201; H10K 59/1213

(57) ABSTRACT

A display device is provided. The display device includes: a base substrate; an active layer on the base substrate, the active layer including a contact region and a channel region; a gate electrode overlapping the channel region of the active layer; a gate insulation layer between the active layer and the gate electrode; an insulating interlayer on the gate electrode on the base substrate and having stepped surfaces and an inclined surface that connects the stepped surfaces; a stopper layer on the insulating interlayer, the stopper layer exposing at least a portion of the inclined surface; a contact electrode penetrating the insulating interlayer to be connected to the contact region of the active layer; and a display element connected to the contact electrode.

### CROSS-REFERENCE TO RELATED APPLICATION

This application is based on and claims priority to Korean Patent Application No. 10-2024-0168485, filed on Nov. 22, 2024, in the Korean Intellectual Property Office, the disclosure of which is incorporated by reference herein in its entirety.

### BACKGROUND

The present disclosure relates to a display device, a method of manufacturing the display device and an electronic device including the display device. More particularly, the present disclosure relates to a display device including a transistor and electrode, a method of manufacturing the display device and the electronic device including the display device.

In a display device such as an organic light emitting diode (OLED) display device and a liquid crystal display (LCD) device, a display substrate including, e.g., a thin film transistor (TFT) and various wirings may be provided, and a display structure including electrodes and emission layers may be formed on the display substrate.

For example, electrodes connecting the TFT and the display structure may be arranged. Recently, various constructions of the TFT and the electrodes for stable implementation of a high-resolution display device have been researched

### SUMMARY

One or more embodiments provide a display device having improved electrical properties and structural reliability.

One or more embodiments also provide a method of manufacturing a display device having improved electrical properties and structural reliability.

One or more embodiments also provide an electronic device having improved electrical properties and structural reliability.

According to an aspect of an embodiment, a display device includes: a base substrate; an active layer on the base substrate, the active layer including a contact region and a channel region; a gate electrode overlapping the channel region of the active layer; a gate insulation layer between the active layer and the gate electrode; an insulating interlayer on the gate electrode on the base substrate and having stepped surfaces and an inclined surface that connects the stepped surfaces; a stopper layer on the insulating interlayer, the stopper layer exposing at least a portion of the inclined surface or having a thickness reduced on the inclined surface compared to a thickness on the stepped surfaces; a contact electrode penetrating the insulating interlayer to be connected to the contact region of the active layer; and a display element connected to the contact electrode.

The stopper layer may include an amorphous carbon layer.

The stepped surfaces may include a first stepped surface positioned over a top surface of the gate electrode and a second stepped surface at a height between the first stepped surface and the base substrate, and the stopper layer may include a first portion on the first stepped surface and a second portion on the second stepped surface.

The first portion and the second portion may be spaced apart by the inclined surface of the insulating interlayer.

An end portion of the first portion or the second portion may extend onto the inclined surface.

The stopper layer may include an inclined portion formed on the inclined surface of the insulating interlayer, and the inclined portion may be thinner than each of the first portion and the second portion.

The first stepped surface and the second stepped surface may be are parallel to a top surface of the base substrate.

The contact electrode may include a contact portion penetrating the insulating interlayer and a wiring portion on a top surface of the insulating interlayer, and the wiring portion may contact the stopper layer on one or more of the stepped surfaces.

The wiring portion may contact the inclined surface of the insulating interlayer.

The insulating interlayer may include: a first insulating interlayer on the active layer and the gate electrode, the first insulating interlayer including silicon oxide; and a second insulating interlayer on the first insulating interlayer, the second insulating interlayer including silicon nitride.

The active layer may include an oxide semiconductor.

The gate electrode may include a sequentially stacked structure of a first metal layer, a second metal layer, and a third metal layer.

The inclined surface of the insulating interlayer may face a side surface of the gate electrode.

According to another aspect of an embodiment, a method of manufacturing a display device includes: forming a first active layer on a base substrate; forming a first gate insulation layer on the first active layer on the base substrate; forming a first gate electrode overlapping the first active layer on the first gate insulation layer; forming a second gate insulation layer on the first gate electrode on the first gate insulation layer; forming a second active layer on the second gate insulation layer; forming a third gate insulation layer on the second active layer; forming a second gate electrode overlapping the second active layer on the third gate insulation layer; forming an insulating interlayer on the second gate electrode, the insulating interlayer including stepped surfaces and an inclined surface that connects the stepped surfaces; forming a stopper layer on the insulating interlayer; performing an etchant treatment to at least partially remove a portion of the stopper layer formed on the inclined surface of the insulating interlayer; forming contact electrodes penetrating the insulating interlayer to be connected to each of the first active layer and the second active layer; and forming a display element connected to at least one of the contact electrodes.

The method may further include forming a contact hole penetrating the stopper layer and the insulating interlayer, the contact hole may partially expose the first active layer before performing the etchant treatment. The etchant treatment may include removing an etching residue in the contact hole.

A portion of the stopper layer of the insulating interlayer may remain on the stepped surfaces after the etchant treatment.

The etchant treatment may include a buffer oxide etchant (BOE) treatment.

The first active layer may include a silicon-based semiconductor and the second active layer may include an oxide semiconductor.

According to another aspect of an embodiment, an electronic device includes: a display device; a memory; and a processor executing data included in the memory to control an operation of the display device. The display device includes: a base substrate; an active layer on the base substrate, the active layer including a contact region and a channel region; a gate electrode overlapping the channel region of the active layer; a gate insulation layer between the active layer and the gate electrode; an insulating interlayer on the gate electrode on the base substrate and having stepped surfaces and an inclined surface connecting the stepped surfaces; a stopper layer on the insulating interlayer, the stopper layer exposing at least a portion of the inclined surface or having a thickness reduced on the inclined surface compared to a thickness on the stepped surfaces; a contact electrode penetrating the insulating interlayer to be connected to the contact region of the active layer; and a display element connected to the contact electrode.

The electronic device may form at least one of a flat panel display, a curved display, a computer monitor, a medical monitor, a television, a billboard, an indoor or outdoor lighting, a signal lighting, a head-up display, a transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle, a video wall, a theater or stadium screen, or a phototherapy device.

In the display device according to embodiments of the present disclosure, a stopper layer including, e.g., an amorphous carbon layer may be formed on a surface of an insulating interlayer on a gate electrode and an active layer. Physical and chemical damage such as penetration of an etchant and generation of cracks occurring at an inclined surface of the insulating interlayer may be prevented by the stopper layer. Accordingly, chemical and mechanical stability may be enhanced even in a transistor including a highly stepped structure.

### BRIEF DESCRIPTION OF DRAWINGS

The above and other aspects will be more apparent from the following description of embodiments taken in conjunction with the accompanying drawings.

FIG. 1 is a schematic cross-sectional view illustrating a stacked structure including a thin film transistor in a display device according to embodiments.

FIG. 2 is a schematic cross-sectional view illustrating a stacked structure including a thin film transistor in a display device according to embodiments.

FIGS. 3 to 5 are schematic cross-sectional views illustrating stacked structures including a thin film transistor in a display device according to some embodiments.

FIGS. 6 and 7 are schematic cross-sectional views illustrating display devices according to embodiments.

FIGS. 8 to 20 are schematic cross-sectional views for describing a method of manufacturing a display device according to embodiments.

FIG. 21 is an exploded perspective view illustrating an electronic device according to embodiments.

FIG. 22 is a schematic plan view illustrating an arrangement of pixels of a display device included in an electronic device according to embodiments.

FIG. 23 is a pixel equivalent circuit diagram of a display device according to embodiments.

FIG. 24 is a block diagram of an electronic device in accordance with an embodiment.

FIG. 25 is a schematic diagram of electronic devices in accordance with various embodiments.

### DETAILED DESCRIPTION

Hereinafter, embodiments will be described in more detail with reference to the attached drawings. The same reference numerals are used for indicating the same elements in the drawings, and repeated descriptions of the same elements can be omitted. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

The terms “on”, “connected”, “coupled,” etc., used herein refers to a direct placement/connection/combination, and also refers to a case where another element is interposed two different elements. By contrast, when an element is referred to as being “directly on,” “directly connected to” or “directly coupled to” another element or layer, there are no intervening elements present.

The terms such as “first”, “second”, “below”, “below”, “above,” “above,” etc., are used in a relative sense to distinguish different elements or positions, and do not specify an absolute position or an absolute order.

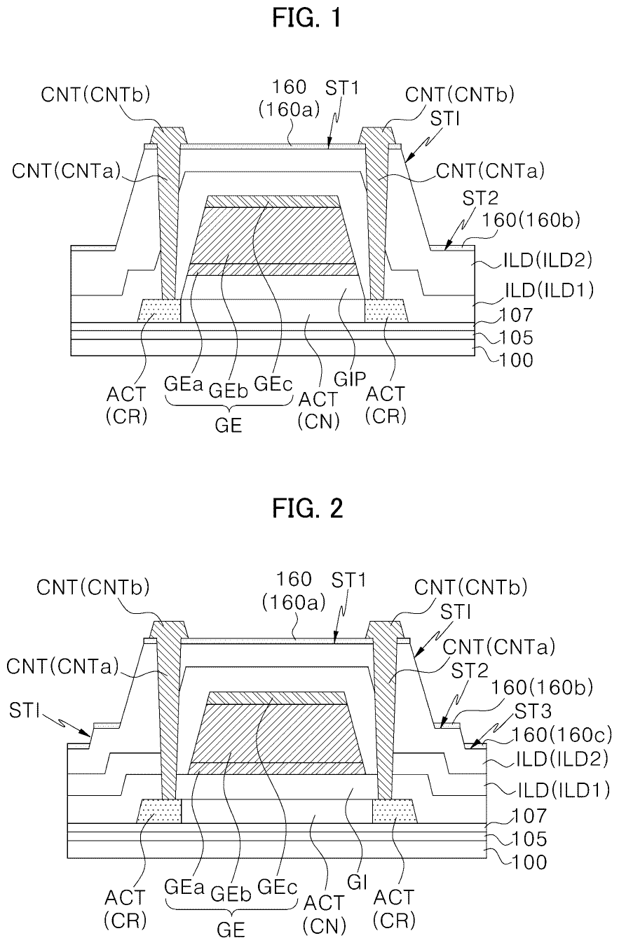

FIG. 1 is a schematic cross-sectional view illustrating a stacked structure including a thin film transistor in a display device according to embodiments.

Referring to FIG. 1, a transistor of a thin film transistor (TFT) type including an active layer ACT may be disposed on a base substrate 100. According to embodiments, a plurality of the transistors may be arranged on the base substrate 100 to provide a display panel in the form of a TFT-array substrate and a display device including the display panel.

As will be described later, the display device includes a light-emitting element connected to the transistor, and the light-emitting element may be connected to the transistor by a contact electrode.

The base substrate 100 may be provided as a back-plane substrate of the display device or the display panel. A glass substrate or a plastic substrate may be used as the base substrate 100.

In some embodiments, the base substrate 100 may include a polymer material having transparency and flexibility. For example, the base substrate 100 may include a polymer material such as polyimide, polysiloxane, an epoxy resin, an acrylic resin, polyester, or the like. In an embodiment, the base substrate 100 may include polyimide.

In some embodiments, a glass substrate may be used as the base substrate 100.

A barrier layer 105 may be formed on a top surface of the base substrate 100. Moisture penetrating through the base substrate 100 may be blocked by the barrier layer 105, and diffusion of impurities between the base substrate 100 and structures formed on the base substrate 100 may be blocked by the barrier layer 105. The barrier layer 105 may entirely cover the top surface of the base substrate 100.

The barrier layer 105 may include, e.g., an inorganic insulating material such as silicon oxide, silicon nitride, or silicon oxynitride, or a combination thereof. In some embodiments, the barrier layer 105 may have a stacked structure including a silicon oxide layer and a silicon nitride layer. In some embodiments, the barrier layer 105 may include an organic layer. In some embodiments, the barrier layer 105 may have a multi-layered structure. For example, the multi-layered structure may include organic and inorganic layers.

A buffer layer 107 may be further disposed on a top surface of the barrier layer 105. Penetration of impurities into the active layer ACT of the thin film transistor may be additionally prevented by the buffer layer 107. The buffer layer 107 may include an inorganic insulating material such as silicon nitride, silicon oxide and/or silicon oxynitride. The buffer layer 107 may have a single-layered structure or a multi-layered structure including one or more of the above-described insulating materials.

The transistor may be disposed on the buffer layer 107. The transistor may include the active layer ACT and a gate electrode GE. A gate insulation layer GIP may be disposed between the active layer ACT and the gate electrode GE.

According to embodiments, the active layer ACT may include an oxide semiconductor such as indium gallium-zinc oxide (IGZO), zinc tin oxide (ZTO), or ITZO. In an embodiment, the active layer ACT may include a silicon-based semiconductor (e.g., polysilicon or amorphous silicon).

The active layer ACT may include a channel region CN and a contact region CR. The contact region CR may have a conductivity greater than that of the channel region CN. For example, the contact region CR may have an impurity concentration or a carrier concentration (e.g., a hydrogen concentration) that is higher than that of the channel region CN.

The contact region CR may be formed at each of both side portions of the channel region CN, and a region between the contact regions CR may be defined as the channel region CN.

For example, the contact regions CR may include a source region adjacent to one side portion of the channel region CN and a drain region adjacent to the other side portion of the channel region CN.

The gate insulation layer GIP may be disposed on the active layer ACT, and for example may substantially cover the channel region CN of the active layer ACT. The gate insulation layer GIP may have a pattern shape partially overlapping (e.g., covering) the active layer ACT. Accordingly, the contact region CR may protrude from the gate insulation layer GIP. For example, a portion of the active layer ACT overlapped by the gate insulation layer GIP may be substantially defined as the channel region CN, whereas portions of the active layer ACT that are exposed by the gate insulation layer GIP may correspond to the contact regions CR.

The gate insulation layer GIP may include an inorganic insulating material such as silicon oxide, silicon nitride, silicon oxynitride, aluminum oxide, titanium oxide, tantalum oxide, hafnium oxide, or the like.

The gate electrode GE may be disposed on the gate insulation layer GIP. The gate electrode GE may overlap the channel region CN in a thickness direction with the gate insulating layer GIP interposed therebetween.

The gate electrode GE may include a metal such as silver (Ag), tungsten (W), molybdenum (Mo), aluminum (Al), copper (Cu), titanium (Ti), chromium (Cr), nickel (Ni), silver (Ag), etc., or an alloy containing at least one therefrom. The gate electrode GE may have a single-layered structure or a multi-layered structure including the above-described metal.

In some embodiments, the gate electrode GE may have a multi-layered structure. As illustrated in FIG. 1, the gate electrode GE may include a first metal layer GEa, a second metal layer GEb, and a third metal layer GEc which may be sequentially stacked from a top surface of the gate insulation layer GIP.

The first metal layer GEa and the third metal layer GEc may include a metal that may be more stable to oxidation or corrosion than that included in the second metal layer GEb. In some embodiments, the first metal layer GEa and the third metal layer GEc may include substantially the same metal. The second metal layer GEb may include a metal having a resistance less than that of the first metal layer GEa and the third metal layer GEc. A thickness of the second metal layer GEb may be greater than a thicknesses of each of the first metal layer GEa and the third metal layer GEc.

In an embodiment, the first metal layer GEa, the second metal layer GEb, and the third metal layer GEc may be a Ti layer, an Al layer, and a Ti layer, respectively.

The transistor in the form of the thin film transistor may be defined by the active layer ACT, the gate insulation layer GIP and the gate electrode GE as described above.

An insulating inlayer ILD may be formed on the base substrate 100 or the buffer layer 107 to overlap the gate electrode GE. For example, the insulating inlayer ILD may cover the gate electrode GE. In some embodiments, the insulating interlayer ILD may cover the contact regions CR of the active layer ACT. In some embodiments, the insulating interlayer ILD may cover the gate insulation layer GIP. In some embodiments, the insulating interlayer ILD may have a multi-layered structure including a first insulating interlayer ILD1 and a second insulating interlayer ILD2.

The first insulating inlayer ILD1 may be on the contact region CR of the active layer ACT, the gate insulation layer GIP and the gate electrode GE. For example, the first insulating inlayer ILD1 may cover the contact region CR of the active layer ACT, the gate insulation layer GIP and the gate electrode GE. The second insulating interlayer ILD2 may be formed on the first insulating interlayer ILD1.

In some embodiments, the first insulating interlayer ILD1 may be in contact with the contact region CR. For example, the first insulating interlayer ILD1 may be in direct contact with the contact region CR. The first insulating interlayer ILD1 may also be in contact with the gate electrode GE. For example, first insulating interlayer ILD1 may be in direct contact with the gate electrode GE. The second insulating interlayer ILD2 may be physically spaced apart from the contact region CR and the gate electrode GE with the first insulating interlayer ILD1 interposed therebetween.

The insulating interlayer ILD may include an inorganic insulation material such as silicon oxide, silicon nitride, silicon oxynitride, aluminum oxide, titanium oxide, tantalum oxide, hafnium oxide, or the like. The first insulating interlayer ILD1 and the second insulating interlayer ILD2 may include different inorganic insulating materials. In some embodiments, the first insulating interlayer ILD1 may include silicon oxide (SiOx), and the second insulating interlayer ILD2 may include silicon nitride (SiNx).

The insulating interlayer ILD may be conformally formed along a top surface profile of a structure disposed on the base substrate 100. As illustrated in FIG. 1, the insulating interlayer ILD may have a stepped portion according to heights of the contact region CR and the gate electrode GE of the active layer ACT.

According to embodiments, the insulating interlayer ILD may include a first stepped surface ST1 and a second stepped surface ST2, and may include an inclined surface STI disposed between the first stepped surface ST1 and the second stepped surface ST2 to connect the first stepped surface ST1 and the second stepped surface ST2.

The first stepped surface ST1 may be higher than the second stepped surface ST2 with respect to the top surface of the base substrate 100. A height of the first stepped surface ST1 may be greater than a height of the second stepped surface ST2. According to embodiments, each of the first stepped surface ST1 and the second stepped surface ST2 may be a substantially flat or planar surface. For example, the first stepped surface ST1 and the second stepped surface ST2 may be substantially parallel to the top surface of the base substrate 100. For example, the inclined surface STI may face a side surface of the gate electrode GE.

According to embodiments, a stopper layer 160 may be disposed on a top surface of the insulating interlayer ILD. The stopper layer 160 may be directly formed on the top surface of the insulating interlayer ILD.

The stopper layer 160 may include a first portion 160a disposed on the first stepped surface ST1 of the insulating interlayer ILD and a second portion 160b disposed on the second stepped surface ST2 of the insulating interlayer ILD. The first portion 160a and the second portion 160b may be physically separated from or spaced apart from each other with the inclined surface STI interposed therebetween.

According to embodiments, the stopper layer 160 may not substantially cover the inclined surface STI of the insulating interlayer ILD. Accordingly, the stopper layer 160 may not be in contact with the inclined surface STI of the insulating interlayer ILD.

The stopper layer 160 may include a carbon layer. In example embodiments, the stopper layer 160 may include an amorphous carbon layer. In some embodiments, the stopper layer 160 may be a carbon layer or an amorphous carbon layer that is a substantially single layer.

A thickness of the stopper layer 160 may be smaller than a thickness of the insulating interlayer ILD. In this regard, the stopper layer 160 may be thinner than the insulating interlayer ILD. The thickness of the stopper layer 160 may be less than a thickness of each of the first insulating interlayer ILD1 and the second insulating interlayer ILD2. In this regard, the stopper layer 160 may be thinner than each of the first insulating interlayer ILD1 and the second insulating interlayer ILD2.

The contact region CR of the active layer ACT may be connected to a contact electrode CNT. The contact electrode CNT may be provided as a connection electrode connecting the active layer ACT with a wiring of a pixel circuit. For example, the contact electrode CNT may include a source electrode connected to the source region at one side of the contact regions CR and a drain electrode connected to the drain region at the other side of the contact regions CR.

The contact electrode CNT may penetrate the insulating interlayer ILD to be in contact with or electrically connected to the contact region CR. The contact electrode CNT may include a contact portion CNTa and a wiring portion CNTb. The contact portion CNTa may penetrate the insulating interlayer ILD to be in contact with or electrically connected to the contact region CR. In some embodiments, the contact portion CNTa may penetrate the contact region CR. The wiring portion CNTb may be disposed on the insulating interlayer ILD (or the top surface of the second insulating interlayer ILD2) and may have a width greater than that of the contact portion CNTa. The contact portion CNTa and the wiring portion CNTb may be a single member substantially integral with each other.

The contact electrode CNT may be in contact with the stopper layer 160. For example, the contact electrode CNT may be in direct contact with the stopper layer 160. In example embodiments, a bottom surface of the wiring portion CNTb of the contact electrode CNT may be in contact with the stopper layer 160. In some embodiments, the bottom surface of the wiring portion CNTb may be in contact with the first portion 160a of the stopper layer 160. For example, the bottom surface of the wiring portion CNTb may be in direct contact with the first portion 160a of the stopper layer 160.

The contact electrode CNT may include the above-described metal or alloy. In some embodiments, the contact electrode CNT may have a stacked structure substantially the same as or similar to that of the gate electrode GE.

According to embodiments described above, the stopper layer 160 may be on the top surface of the insulating interlayer ILD. For example, the stopper layer 160 may cover the top surface of the insulating interlayer ILD. Accordingly, deterioration and damages of the active layer ACT due to defects of the insulating interlayer ILD caused in a subsequent etching process after the formation of the insulating interlayer ILD may be prevented.

The insulating interlayer ILD may include an inclined region having a relatively low layer quality due to a step difference caused by the gate electrode GE and the gate insulation layer GIP. For example, as a deposition angle of a deposition source for the formation of the insulating interlayer ILD may be limited by a high stepped structure, and stability and strength of the layer may be deteriorated on a sidewall of the high steppe structure due to a reduction in deposition density.

As will be described later, the stopper layer 160 may also be formed on the inclined surface STI, and then removed from the inclined surface STI by a subsequent etching solution treatment while preventing layer damages and degradation of the active layer through the inclined surface STI of the insulating interlayer ILD.

FIG. 2 is a schematic cross-sectional view illustrating a stacked structure including a thin film transistor in a display device according to embodiments. Detailed descriptions on structures and elements substantially the same as or similar to those described with reference to FIG. 1 are omitted.

Referring to FIG. 2, the gate insulation layer GI may be formed as a continuous layer on the active layer ACT. For example, the gate insulation layer GI may be formed as a continuous layer covering the active layer ACT. For example, the gate insulation layer GI may cover the contact region CR together with the channel region CN of the active layer ACT. The gate insulation layer GI may be a common layer in a plurality of transistors or a plurality of pixels.

In this case, the contact portion CNTa of the contact electrode CNT may penetrate the insulating interlayer ILD and the gate insulation layer GI to be in contact with or be connected to the contact region CR. In some embodiments, the contact portion CNTa may penetrate the contact region CR.

In some embodiments, the insulating interlayer ILD may include an additional stepped portion. For example, the additional stepped portion may be generated in the insulating interlayer ILD by the gate insulation layer GI. As illustrated in FIG. 2, the insulating interlayer ILD may include a third stepped surface ST3, a second stepped surface ST2, and a first stepped surface ST1 sequentially located in a height direction with respect to the top surface of the base substrate 100. Each of the first to third stepped surfaces ST1, ST2 and ST3 may be a flat or planar surface substantially parallel to the top surface of the base substrate 100.

The inclined surface STI may be located between the first stepped surface ST1 and the second stepped surface ST2, and between the second stepped surface ST2 and the third stepped surface ST3.

The stopper layer 160 may include a first portion 160a, a second portion 160b and a third portion 160c disposed on the first stepped surface ST1, the second stepped surface ST2 and the third stepped surface ST3, respectively. The first portion 160a, the second portion 160b and the third portion 160c may be physically spaced apart from or separated from each other by the inclined surface STI of the insulating interlayer ILD.

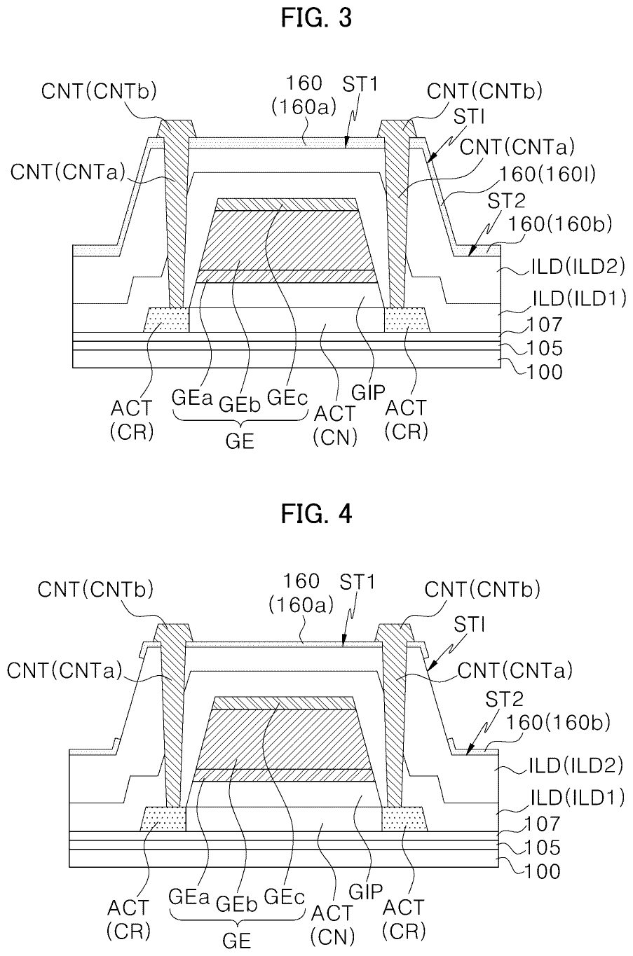

FIGS. 3 to 5 are schematic cross-sectional views illustrating stacked structures including a thin film transistor in a display device according to some embodiments. Detailed descriptions on elements and structures substantially the same as or similar to those described with reference to FIG. 1 are omitted.

Referring to FIG. 3, according to some embodiments, the stopper layer 160 may also be formed on the inclined surface STI of the insulating interlayer ILD.

According to embodiments, the stopper layer 160 may continuously extend on the first stepped surface ST1, the inclined surface STI and the second stepped surface ST2, and a thickness of the stopper layer 160 may be relatively reduced on the inclined surface STI. For example, a portion of the stopper layer 160 extending on the inclined surfaces STI may be thinner than portions of the stopper layer 160 extending on the first stepped surface ST1 and the second stepped surface ST2.

As described above, the stopper layer 160 may include the first portion 160a formed on the first stepped surface ST1 and the second portion 160b formed on the second stepped surface ST2, and may further include an inclined portion 160I formed on the inclined surface STI. A thickness of the inclined portion 160I may be less than the thickness of the first portion 160a and less than the thickness of the second portion 160b.

Referring to FIG. 4, according to some embodiments, the stopper layer 160 may be provided on the stepped surfaces ST1 and ST2, and a portion of the inclined surface STI. For example, the stopper layer 160 may cover the stepped surfaces ST1 and ST2, and may partially cover the inclined surface STI.

In some embodiments, an end portion of the first portion 160a of the stopper layer 160 may extend on the inclined surface STI. An end portion of the second portion 160b of the stopper layer 160 may extend on the inclined surface STI. The end portion of the first portion 160a and the end portion of the second portion 160b may be physically separated from or spaced apart from each other on the inclined surface STI.

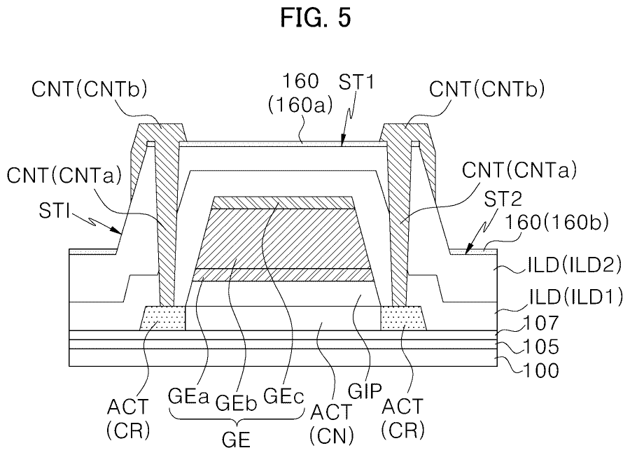

Referring to FIG. 5, according to some embodiments, a portion of the contact electrode CNT may be in contact with the inclined surface STI.

For example, the wiring portion CNTb of the contact electrode CNT may be in contact with the first portion 160a of the stopper layer 160 on the first stepped surface ST1, and may be in contact with the inclined surface STI of the insulating interlayer ILD. For example, the wiring portion CNTb of the contact electrode CNT may be in direct contact with the first portion 160a of the stopper layer 160 on the first stepped surface ST1, and may be in direct contact with the inclined surface STI of the insulating interlayer ILD. The wiring portion CNTb may be in contact with surfaces of different materials, so that mechanical failures such as peel-off and detachment of the contact electrode CNT may be prevented.

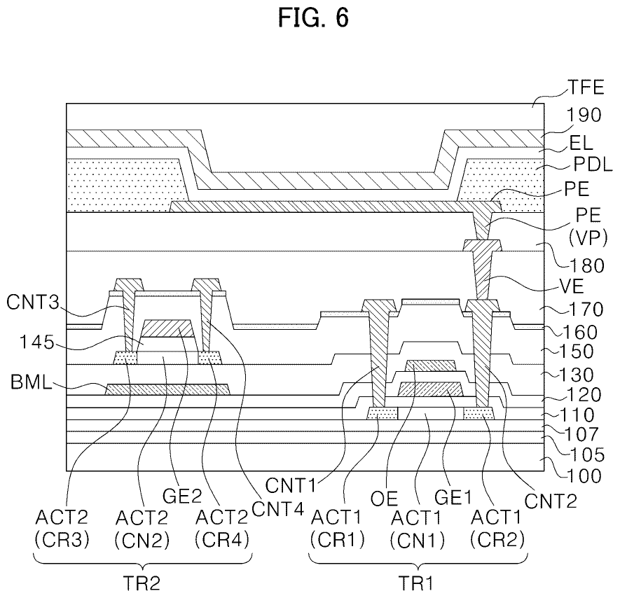

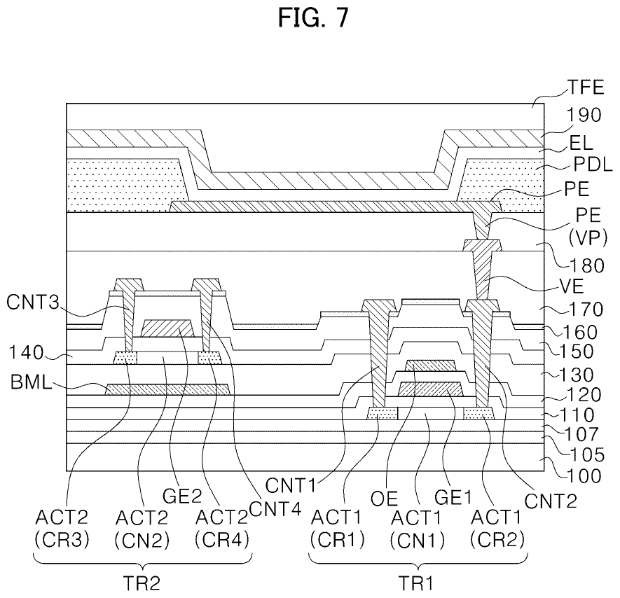

FIGS. 6 and 7 are schematic cross-sectional views illustrating display devices according to embodiments. Detailed descriptions of materials, elements and structures substantially the same as or similar to those described with reference to FIG. 1 are omitted.

Referring to FIG. 6, the display device may include a first transistor element TR1 and a second transistor element TR2.

The first transistor element TR1 may include a first active layer ACT1 including a first channel region CN1 and first and second contact regions CR1 and CR2, a first gate insulation layer 110, and a first gate electrode GE1. The first transistor element TR1 may serve as a pixel driving transistor.

The first active layer ACT1 may include the above-mentioned silicon-based semiconductor material. The first and second contact regions CR1 and CR2 may be formed as a p-doped region or a p+ doped region.

The first gate insulation layer 110 may be formed on the buffer layer 107 and, for example, may cover the first active layer ACT1. The first gate insulation layer 110 may substantially cover an entire top surface of the buffer layer 107.

The first gate electrode GE1 may overlap the first channel region CN1 of the first active layer ACT1 in a thickness direction or a height direction with the first gate insulation layer 110 interposed therebetween.

A second gate insulation layer 120 may be formed on the first gate insulation layer 110, and for example may cover the first gate electrode GE1. An overlapping electrode OE1 may be disposed on the second gate insulation layer 120. The overlapping electrode OE1 may overlap the first gate electrode GE1 in a thickness direction or a height direction with the second gate insulation layer 120 interposed therebetween.

In some embodiments, the overlapping electrode OE may serve as an upper gate electrode of the first transistor element TR1. In some embodiments, a storage capacitor may be formed by the overlapping electrode OE, the second gate insulation layer 120 and the first gate electrode GE1.

A lower insulating interlayer layer 130 may be formed on the second gate insulation layer 120, and for example, may cover the overlapping electrode OE. In some embodiments, a rear metal layer BML may be further formed on the second gate insulation layer 120 together with the overlapping electrode OE. In this case, the lower insulating interlayer 130 may be on (for example, may cover) the rear metal layer BML and the overlapping electrode OE. For example, the rear metal layer BML may be spaced apart from the overlapping electrode OE.

The second transistor element TR2 may include a second active layer ACT and a second gate electrode GE2. The second gate electrode GE2 may overlap a second channel region CN2 of the second active layer ACT2 in a thickness direction or a height direction with a third gate insulating layer 145 interposed therebetween. The second transistor element TR2 may serve as a switching transistor.

The third gate insulation layer 145 may have a shape or a structure substantially the same as or similar to that of the gate insulation layer GIP as illustrated in FIG. 1. The third gate insulation layer 145 may have a pattern shape selectively on the second channel region CN2 of the second active layer ACT2. For example, the third gate insulation layer 145 may cover the second channel region CN2 of the second active layer ACT2.

The second active layer ACT2 may overlap the rear metal layer BML in the thickness direction or the height direction. The rear metal layer BML may serve as a blocking layer with respect to an external light for the second transistor element TR2. The rear metal layer BML may serve as a bias electrode or a back-gate electrode. In an embodiment, the rear metal layer BML may be an island-shaped floating electrode separated from other wires or electrodes.

The second active layer ACT2 of the second transistor element TR2 may be disposed at an upper level with respect to the top surface of the base substrate 100 relatively to the first active layer ACT1 of the first transistor element TR1. According to embodiments, the second active layer ACT2 may be disposed on a top surface of the lower insulating interlayer 130.

The second active layer ACT2 may include the above-mentioned oxide semiconductor, and a third contact region CR3 and a fourth contact region CR4 may be formed at one side and the other side, respectively, of the second active layer ACT2. For example, the third contact region CR3 and the fourth contact region CR4 may serve as a source region and a drain region of the second active layer ACT2, respectively.

A portion of the second active layer ACT2 between the third contact region CR3 and the fourth contact region CR4 may be defined as the second channel region CN2. The third contact region CR3 and the fourth contact region CR4 may be formed as, e.g., an n-doped region or an n+-doped region.

An insulating interlayer 150 may be formed on the lower insulating interlayer 130, and for example may cover the second gate electrode GE2 and the third gate insulation layer 145. The insulating interlayer 150 may be provided as an upper insulating interlayer on both the first transistor element TR1 and the second transistor element TR2. For example, the insulating interlayer 150 may cover both the first transistor element TR1 and the second transistor element TR2.

The insulating interlayer 150 may include substantially the same structure and material as those of the insulating interlayer ILD described with reference to FIGS. 1 to 5. As described with reference to FIGS. 1 to 5, the insulating interlayer 150 may have a multi-layered structure of the first insulating interlayer ILD1 and the second insulating interlayer ILD2, and may include stepped surfaces and inclined surfaces generated by stepped portions generated by the gate electrodes GE1 and GE2.

A stopper layer 160 may be formed on the stepped surfaces on the insulating interlayer 150, and may have a discontinuous shape due to the inclined surfaces. In some embodiments, as described with reference to FIGS. 1 and 2, the stopper layer 160 may not extend along the inclined surfaces. In this regard, the inclined surfaces may be exposed by the stopper layer 160.

In some embodiments, as described with reference to FIG. 3, the stopper layer 160 may have a relatively small thickness on the inclined surface. In some embodiments, as described with reference to FIG. 4, the stopper layer 160 may partially extend onto a part of the inclined surface.

A first contact electrode CNT1 and a second contact electrode CNT2 may penetrate the insulating interlayer 150, the lower insulating interlayer 130, the second gate insulation layer 120, and the first gate insulation layer 110 to be in contact with or be connected to the first contact region CR1 and the second contact region CR2 of the first active layer ACT1, respectively. In some embodiment, the first contact electrode CNT1 may penetrate the first contact region CR1, and the second contact electrode CNT2 may penetrate the second contact region CR2.

A third contact electrode CNT3 and a fourth contact electrode CNT4 may penetrate the insulating interlayer 150 to be in contact with or be connected to the third contact region CR3 and the fourth contact region CR4 of the second active layer ACT2, respectively. In some embodiment, the third contact electrode CNT3 may penetrate the third contact region CR3, and the fourth contact electrode CNT4 may penetrate the fourth contact region CR4. Wiring portions of the contact electrodes CNT1, CNT2, CNT3 and CNT4 may be disposed on a top surface of the insulating interlayer 150 to be in contact with the stopper layer 160. For example, the wiring portions of the contact electrodes CNT1, CNT2, CNT3 and CNT4 may be in direct contact with the stopper layer 160.

A planarization layer on (for example, covering) the stopper layer 160, and the contact electrodes CNT1, CNT2, CNT3 and CNT4 may be formed on the insulating interlayer 150. A display element electrically connected to the transistor element through a pixel electrode PE may be disposed on the planarization layer.

In some embodiments, the planarization layer may include a first planarization layer 170 and a second planarization layer 180. The first planarization layer 170 may be formed on the insulating interlayer 150 on (and for example, may cover) the stopper layer 160 and the contact electrodes CNT1, CNT2, CNT3 and CNT4. In some embodiments, the insulating interlayer 150 may be in direct contact with the first planarization layer 170. For example, at least a portion of an inclined surface of the insulating interlayer 150 may be in direct contact with the first planarization layer 170.

A via electrode VE may penetrate the first planarization layer 170 to be connected to or in contact with, e.g., the second contact electrode CNT2 of the first transistor element TR1. The via electrode VE may include a wiring portion disposed on a top surface of the first planarization layer 170.

The second planarization layer 180 may be formed on the first planarization layer 170, and for example may cover the via electrode VE.

The planarization layers 170 and 180 may include an organic material such as polyimide, an epoxy resin, an acrylic resin, polyester, a siloxane resin, benzocyclobutene (BCB), or the like. The via electrode VE may Include the above-described metal or alloy.

The pixel electrode PE may be disposed on the second planarization layer 180 and may be electrically connected to the via electrode VE. For example, the pixel electrode PE may include a via portion VP penetrating the second planarization layer 180 to be in contact with or connected to a top surface of the wiring portion of the via electrode VE.

The display element may include a light-emitting element. The light-emitting element may include the pixel electrode PE, a light-emitting portion EL, and a counter electrode 190.

The pixel electrode PE may serve as an anode, and may include a high work function conductive material that promotes hole injection. The pixel electrode PE may be formed as a transmissive electrode. The pixel electrode PE may include a transparent conductive oxide such as indium tin oxide (ITO), indium zinc oxide (IZO), zinc oxide (ZnO), and indium tin oxide (ITZO). The pixel electrode PE may electrically connect the light-emitting portion EL with the second contact electrode CNT2 of the first transistor element TR1.

The pixel electrode PE may be formed as a translucent electrode or a reflective electrode. The pixel electrode PE may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more thereof.

The pixel electrode PE may have a single-layered structure or a multi-layered structure. For example, the pixel electrode PE may have a triple-layered structure of ITO/Ag/ITO.

A pixel defining layer PDL may be formed on the second planarization layer 180 to expose a top surface of the pixel electrode PE. A pixel region may be defined by a sidewall of the pixel defining layer PDL. For example, a blue light-emitting region, a green light-emitting region, and a red light-emitting region may be separated/defined by the pixel defining layer PDL, and the light-emitting element may include a blue light-emitting element, a green light-emitting element, and a red light-emitting element.

In some embodiments, all of the light-emitting elements may be white light-emitting elements or blue light-emitting elements.

The light-emitting portion EL may be disposed in each light-emitting region formed by the pixel defining layer PDL. According to embodiments, the light-emitting portion EL may include an emission layer including an organic light-emitting material. For example, the emission layer may include a fluorescent host and/or a host for a phosphorescent device, and may further include a fluorescent dopant, a phosphorescent dopant, and/or a thermally activated delayed fluorescent (TADF) dopant.

For example, the light-emitting portion EL may be formed by a process such as a vacuum deposition, a spin coating, an inkjet printing, a laser printing, a casting, a laser thermal transfer, or the like.

The counter electrode 190 may be disposed on the light-emitting portion EL. The counter electrode 190 may be a common electrode continuously extending throughout a plurality of the light-emitting regions or pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in combination thereof.

The counter electrode 190 may be formed as a transmissive electrode, a translucent electrode, or a reflective electrode. The counter electrode 190 may have a single-layered structure or a multi-layered structure.

The light-emitting portion EL may further include a hole transport layer and an electron transport layer. According to embodiments, the hole transport layer, the emission layer, the electron transport layer, and the counter electrode 190 may be sequentially stacked from a top surface of the pixel electrode PE.

For example, the hole transport layer may include a hole transporting material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″tris[N(2-naphthyl)-N-phenylamino]-triphenylamine), NPB (N,N′-di(naphthalene-l-yl)-N,N′-diphenyl-benzidine), TPD (N,N′-bis(3-methylphenyl)-N,N′-diphenyl-[1,1′-biphenyl]-4,4′-diamine), TCTA (4,4′,4″tris(N-carbazolyl)triphenylamine), PEDOT/PSS (poly(3,4-ethylenedioxythiophene)/poly(4-styrenesulfonate)), or the like.

For example, the electron transport layer may include an electron transporting material such as TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the pixel electrode PE and the hole transport layer. An electron injection layer may be further disposed between the counter electrode 190 and the electron transport layer.

In some embodiments, the emission layer included in the light-emitting portion EL may be patterned individually within the light-emitting region defined by the pixel defining layer PDL. Accordingly, the emission layer may be separated from each other in the form of an island pattern spaced apart from each other in each of a plurality of pixels.

In some embodiments, layers (e.g., the hole transport layer and the electron transport layer) included in the light-emitting portion EL may extend continuously and commonly throughout a plurality of the light-emitting regions and a top surface of the pixel defining layer PDL.

An encapsulation layer TFE may be formed on the counter electrode 190. The encapsulation layer TFE may be disposed on the pixel defining layer PDL and the light-emitting elements to protect the light-emitting elements from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate, polyacrylic acid, etc.), an epoxy resin (e.g., aliphatic glycidyl ether (AGE), or a combination thereof. The encapsulation layer TFE may include a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer and a second inorganic layer.

In some embodiments, a color control layer overlapping the light-emitting portion EL may be disposed on the encapsulation layer TFE. The color control layer may include a color conversion layer including quantum dots and/or a color filter.

Referring to FIG. 7, a third gate insulation layer 140 may have a shape substantially the same as or similar to that of the gate insulation layer GI described with reference to FIG. 2.

The third gate insulation layer 140 may be formed on the lower insulating interlayer 130, and for example may cover the contact regions CR3 and CR4 of the second active layer ACT2 included in the second transistor element TR2. The third gate insulation layer 140 may be formed on an entire top surface of the lower insulating interlayer 130, and may also cover the first transistor device element TR1.

The first and second contact electrodes CNT1 and CNT2 may penetrate the insulating interlayer 150, the third gate insulation layer 140, the lower insulating interlayer 140, the second gate insulation layer 120 and the first gate insulation layer 110, and may be in contact with or connected to the first and second contact regions CR1 and CR2 of the first active layer ACT1, respectively. The first and second contact electrodes CNT1 and CNT2 may penetrate the first and second contact regions CR1 and CR2 of the first active layer ACT1, respectively.

The third and fourth contact electrodes CNT3 and CNT4 may penetrate the insulating interlayer 150 and the third gate insulation layer 140, and may be in contact with or connected to the third and fourth contact regions CR3 and CR4 of the second active layer ACT2, respectively. The third and fourth contact electrodes CNT3 and CNT4 may penetrate the third and fourth contact regions CR3 and CR4 of the second active layer ACT2, respectively.

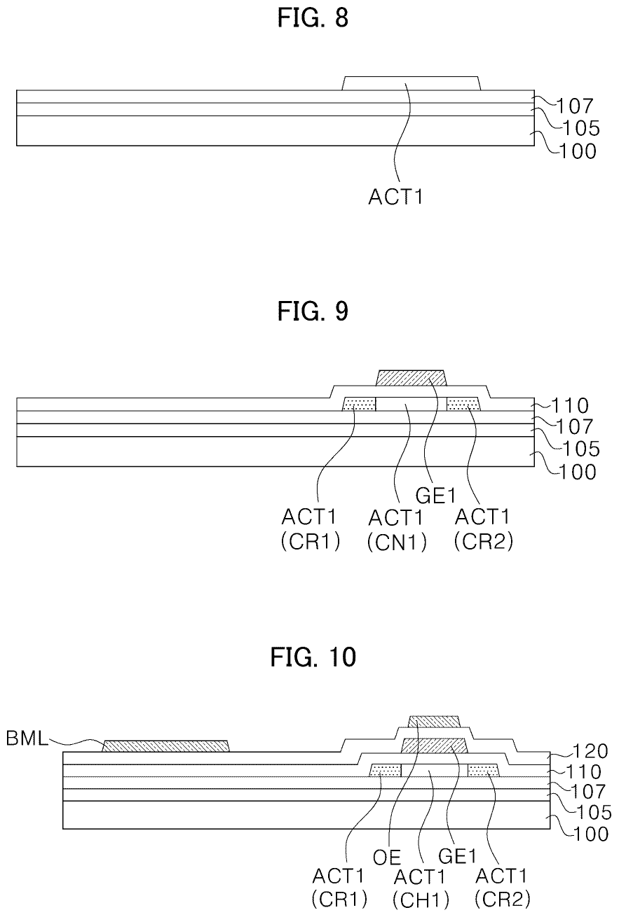

FIGS. 8 to 20 are schematic cross-sectional views illustrating a method of manufacturing a display device according to embodiments. For example, detailed descriptions on materials described with reference to FIG. 1 are omitted.

Referring to FIG. 8, the barrier layer 105 and the buffer layer 107 may be sequentially formed on the base substrate 100, and the first active layer ACT1 may be formed on the buffer layer 107.

The barrier layer 105 and the buffer layer 107 may be formed by a deposition process such as a chemical vapor deposition (CVD) process, a sputtering process, an atomic layer deposition (ALD) process, or the like, to include the inorganic insulating material as described above.

For example, an amorphous silicon layer may be formed on a top surface of the buffer layer 107, and then heat-treated to form a silicon layer. The silicon layer may be patterned by a photo-lithography process to form a first active layer ACT1. In an embodiment, the first active layer ACT1 may be formed as a low-temperature polysilicon (LTPS) layer.

Referring to FIG. 9, the first gate insulation layer 110 on (for example, covering) the first active layer ACT1 may be formed on the buffer layer 107. The first gate insulation layer 110 may be formed by a deposition process such as a CVD process to include the above-mentioned inorganic insulation material.

A first gate electrode GE1 overlapping a portion of the first active layer ACT1 may be formed on the first gate insulation layer 110. A first conductive layer including the above-described metal may be formed by a deposition process such as a sputtering process. The first gate electrode GE1 may be formed by patterning the first conductive layer by a photo-lithography process.

An impurity doping process using the first gate electrode GE1 as an ion implantation mask may be performed. In an embodiment, p-type impurities may be doped at both side portions of the first active layer ACT1 through the ion implantation process or the impurity doping process.

Thus, a conductivity of both side portions of the first active layer ACT1 may be increased to form a first contact region CR1 and a second contact region CR2. A portion of the first active layer ACT1 between the first contact region CR1 and the second contact region CR2, which substantially overlap the first gate electrode GE1, may be defined as the first channel region CN1.

Referring to FIG. 10, the second gate insulation layer 120 on (for example, covering) the first gate electrode GE1 may be formed on the first gate insulation layer 110. The second gate insulation layer 120 may be formed by a deposition process such as a CVD process to include the above-mentioned inorganic insulating material.

A second conductive layer including the above-described metal may be formed on the second gate insulation layer 120 by a deposition process such as a sputtering process. The second conductive layer may be patterned by a photo-lithography process to form the overlapping electrode OE overlapping the first gate electrode GE1 in a thickness direction.

According to embodiments, the rear metal layer BML may be formed from the second conductive layer together with the overlapping electrode OE by the photo-lithography process.

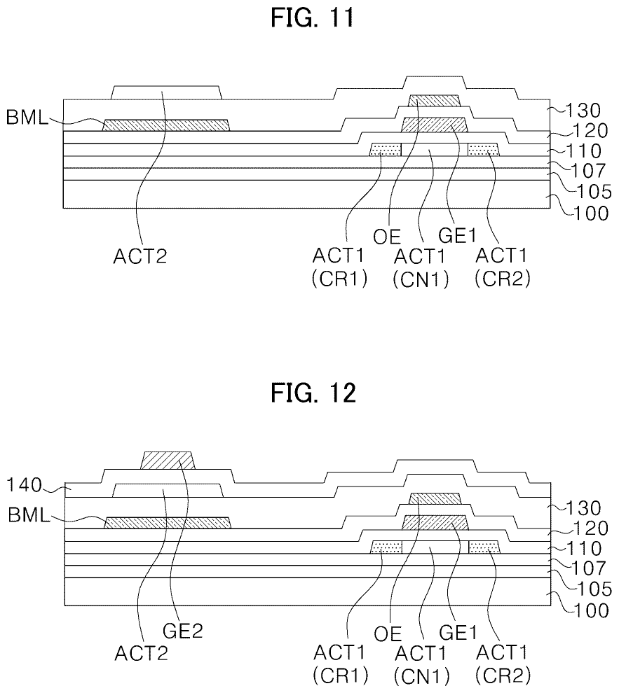

Referring to FIG. 11, the lower insulating interlayer 130 may be formed on the second gate insulation layer 120. For example, the lower insulating interlayer 130 may commonly cover the overlapping electrode OE and the rear metal layer BML. The lower insulating interlayer 130 may be formed by a deposition process such as a CVD process to include the above-mentioned inorganic insulating material.

The second active layer ACT2 overlapping the rear metal layer BML may be formed on the lower insulating interlayer 130. According to embodiments, an oxide semiconductor layer including the above-mentioned oxide semiconductor may be formed on the lower insulating interlayer 130 by a deposition process such as a sputtering process. The oxide semiconductor layer may be patterned by a photo-lithography process to form the second active layer ACT2 overlapping the rear metal layer BML.

Referring to FIG. 12, an insulation layer 140 on the second active layer ACT2 may be formed on the lower insulating interlayer 130. For example, the insulation layer 140 may cover the second active layer ACT2. The insulation layer 140 may be formed by a deposition process such as a CVD process to include the above-mentioned inorganic insulating material.

A third conductive layer including the above-described metal may be formed on the insulation layer 140 by a deposition process such as a sputtering process. The third conductive layer may be patterned by a photo-lithography process to form the second gate electrode GE2 overlapping a portion of the second active layer ACT2.

In some embodiments, the third conductive layer or the second gate electrode GE2 may be formed in a multi-layered structure including the first metal layer, the second metal layer and third the metal layer as described above.

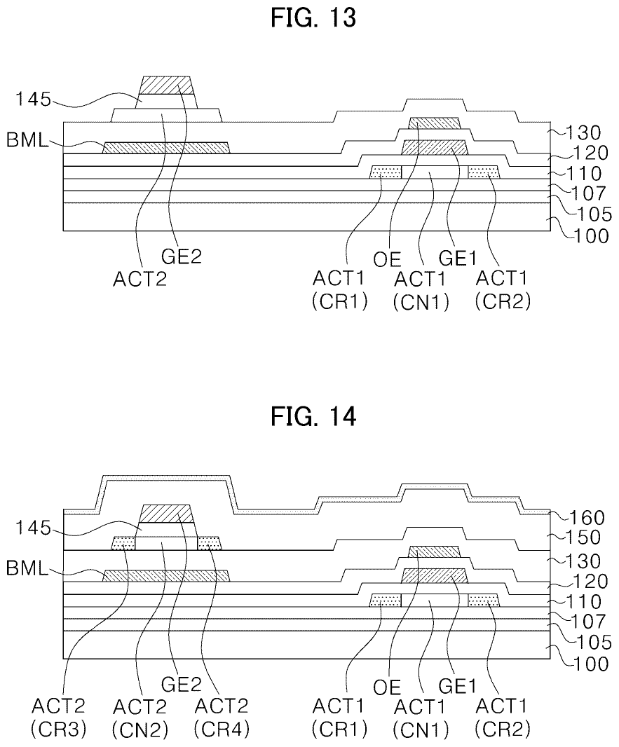

Referring to FIG. 13, the insulation layer 140 may be partially removed using the second gate electrode GE2 as an etching mask to form the third gate insulation layer 145 having a pattern shape on, and for example may partially cover, the second active layer ACT2.

Internal damage sites (e.g., oxygen deficiency sites) may be induced at both side portions of the second active layer ACT2 exposed during the etching process of the insulation layer.

Referring to FIG. 14, the insulating interlayer 150 may be formed on the lower insulating interlayer 130. For example, the insulating interlayer 150 may cover the second active layer ACT2, the third gate insulation layer 145 and the second gate electrode GE2. The insulating interlayer 150 may be formed by a deposition process such as a CVD process to include the above-mentioned inorganic insulating material.

According to embodiments, the insulating interlayer 150 may be formed in a multi-layered structure including the first insulating interlayer ILD1 and the second insulating interlayer ILD2 as described with reference to FIG. 1. In some embodiments, the first insulating interlayer ILD1 on the second active layer ACT2, the third gate insulation layer 145, and the second gate electrode GE2 may be formed to include silicon oxide on the lower insulating interlayer 130. The second insulating interlayer ILD2 may be formed on the first insulating interlayer ILD1 to include silicon nitride.

As the insulating interlayer 150 is formed, hydrogen included in the insulating interlayer 150 may be diffused or transferred to the internal damage sites induced in the second active layer ACT2 to form the third and fourth contact regions CR3 and CR4.

In some embodiments, as described with reference to FIG. 7, the insulating layer 140 may serve as the third gate insulation layer 140 in the form of a continuous layer commonly provided in a plurality of transistors. In this case, impurities such as B+may be injected through the third gate insulation layer 140 and into both side portions of the second active layer ACT2 using the second gate electrode GE2 as an ion implantation mask. Accordingly, the third and fourth contact regions CR3 and CR4 may be formed at one side portion and the other side portion of the second active layer ACT2, respectively.

Thereafter, the stopper layer 160 may be formed on the insulating interlayer 150. The stopper layer 160 may be formed as an amorphous carbon layer. According to embodiments, the stopper layer 160 may be formed by a deposition process such as a CVD process using a carbon source such as acetylene.

The insulating interlayer 150 may include stepped portions generated due to structures such as gate electrodes GE1 and GE2 and the overlapping electrode OE having different heights. The stopper layer 160 may be continuously and conformally formed along stepped surfaces and inclined surfaces included in a top surface of the insulating interlayer 150.

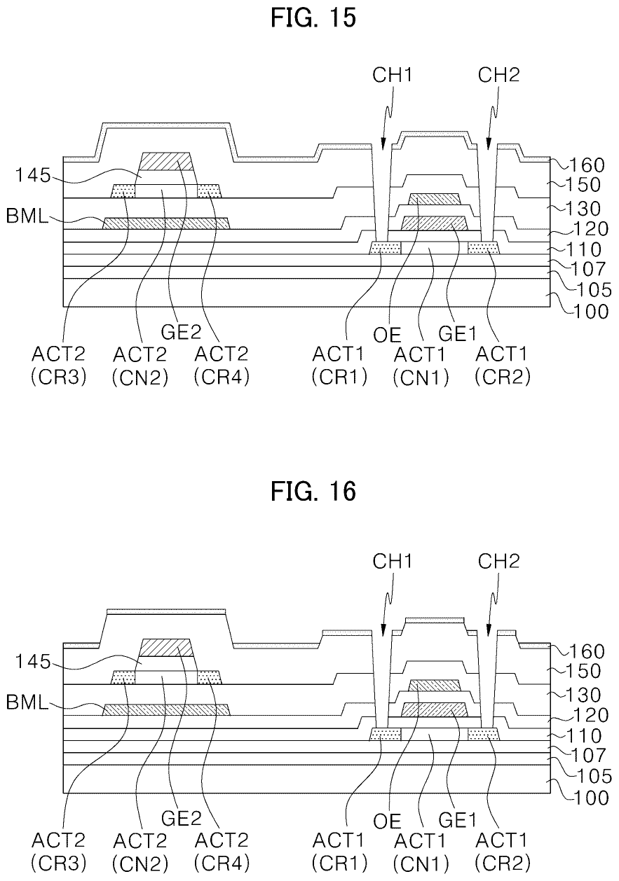

Referring to FIG. 15, a first contact hole CH1 and a second contact hole CH2 exposing the first contact region CR1 and the second contact region CR2, respectively, may be formed.

For example, the stopper layer 160, the insulating interlayer 150, the lower insulating interlayer 130, the second gate insulation layer 120 and the first gate insulation layer 110 may be sequentially etched by an anisotropic etching process such as a dry etching process.

Referring to FIG. 16, an etching residue caused by the above-described etching process of the formation of the contact holes may be removed through an etchant treatment. For example, a natural oxide layer remaining on the first contact region CR1 and the second contact region CR2 exposed through the first contact hole CH1 and the second contact hole CH2, respectively, may be removed through the etchant treatment.

According to embodiments, the etchant treatment may include a buffer oxide etchant (BOE) treatment. The stopper layer 160 may have different etch rates according to locations or angles with respect to an etchant solution used in the BOE treatment. For example, inclined portions of the stopper layer 160 may have a higher etch rate than flat portions of the stopper layer 160 (i.e., on the stepped surfaces of the insulating interlayer 150). The stopper layer 160 may not be etched on the stepped surface of the insulating interlayer 150 that may be a substantially flat surface. The stopper layer 160 on the inclined surface of the insulating interlayer may have relatively high etch rate with respect to the etchant solution, and may be selectively removed during the BOE treatment. As the stopper layer 160 remains on the stepped surfaces of the insulating interlayer 150, the insulating interlayer 150 may be protected.

Accordingly, the stopper layer 160 may be at least partially removed from the inclined surface so that the stopper layer 160 may have a discontinuous shape on the inclined surface of the insulating interlayer 150 as described with reference to FIGS. 1, 2, or 4.

According to embodiments, the stopper layer 160 may be removed on the inclined region of the insulating interlayer 150 having a relatively deteriorated layer quality during the BOE treatment. Thus, penetration of the BOE through the inclined region may be reduced or blocked, and thus chemical and mechanical damages to the second active layer ACT2 caused by the BOE may be prevented.

In some embodiments, as described with reference to FIG. 3, the stopper layer 160 may have a relatively reduced thickness on the inclined surface.

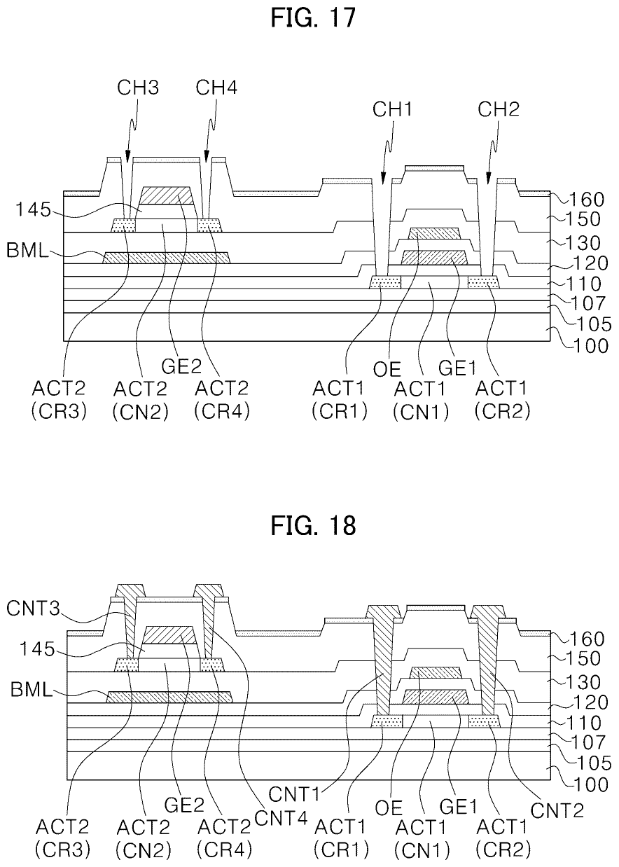

Referring to FIG. 17, the insulating interlayer 150 may be etched by a photo-lithography process to form a third contact hole CH3 and a fourth contact hole CH4 exposing top surfaces of the third and fourth contact regions CR3 and CR4, respectively. During the formation of the third and fourth contact holes CH3 and CH4, the first and second contact holes CH1 and CH2 may be shielded by a mask.

Referring to FIG. 18, a metal layer filling the first to fourth contact holes CH1, CH2, CH3 and CH4 may be formed on the stopper layer 160 or the insulating interlayer 150 by a deposition process such as a sputtering process. Thereafter, the metal layer may be partially etched to form the first contact electrode CNT1, the second contact electrode CNT2, the third contact electrode CNT3 and the fourth contact electrode CNT4 filling the first contact hole CH1, the second contact hole CH2, the third contact hole CH3 and the fourth contact hole CH4 to be connected to the first contact region CR1, the second contact region CR2, the third contact region CR3 and the fourth contact region CR4, Respectively.

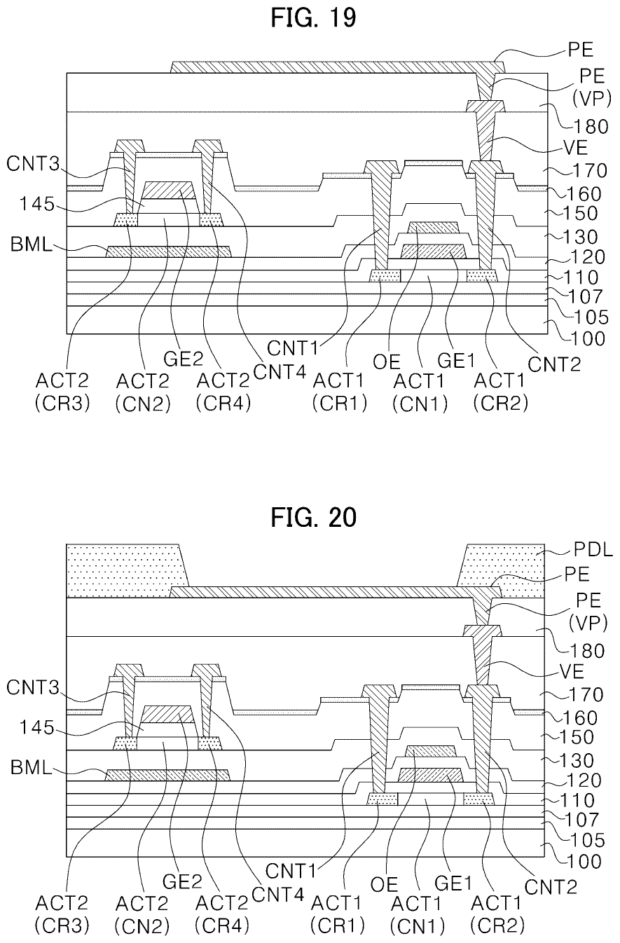

Referring to FIG. 19, a first planarization layer 170 may be formed on the insulating interlayer 150. The first planarization layer 170 may be formed by a coating process such as, e.g., a spin coating process to include the above-mentioned organic insulating material.

The first planarization layer 170 may be partially etched to form, e.g., a first via hole exposing a top surface of the second contact electrode CNT2. A first electrode layer including the above-described metal may be formed on the first planarization layer 170 to fill the first via hole. The first electrode layer may be partially etched to form the via electrode VE.

A second planarization layer 180 on the via electrode VE may be formed on a top surface of the first planarization layer 170. For example, the second planarization layer 180 may cover the via electrode VE. The second planarization layer 180 may be formed by a coating process, e.g., a spin coating process to include the above-mentioned organic insulating material.

The second planarization layer 180 may be partially etched to form a second via hole exposing a top surface of the via electrode VE. A second electrode layer filling the second via hole and including the above-described conductive material may be formed on the second planarization layer 180. The pixel electrode PE may be formed by partially etching the second electrode layer.

Referring to FIG. 20, the pixel defining layer PDL may be formed on the second planarization layer 180. The pixel defining layer PDL may cover a peripheral portion of the pixel electrode PE. In an embodiment, the pixel defining layer PDL may be formed by exposure and development processes after coating a photosensitive organic material such as a polysiloxane resin, a polyimide resin, or an acrylic resin. In an embodiment, the pixel defining layer PDL may be formed by a printing process such as an inkjet printing process using a polymer material or an inorganic material.

Referring again to FIG. 6, the light-emitting portion EL may be formed on a top surface of the pixel electrode PE exposed by the pixel defining layer PDL and a sidewall of the pixel defining layer PDL.

The light-emitting portion EL may be formed by a thermal deposition, an evaporation deposition, a vacuum deposition, a spin coating, an inkjet printing, a laser printing, a casting, a laser thermal transfer, or the like to include the organic light-emitting material as described above.

As described above, the light-emitting portion EL may include the hole transport layer, the emission layer and the electron transport layer.

In some embodiments, the hole transport layer and the electron transport layer may be continuously and commonly formed throughout a plurality of pixels or the pixel electrodes PE, and the pixel defining layer PDL. In some embodiments, the emission layer may be selectively patterned for each pixel electrode PE of an individual pixel.

The counter electrode 190 serving as a common electrode may be formed on the pixel defining layer PDL and the light-emitting portion EL, and the encapsulation layer TFE protecting the pixels and the counter electrode 190 may be formed. The encapsulation layer TFE may be formed to include a multi-layered structure of an inorganic insulation layer and an organic insulation layer. For example, the encapsulation layer TFE may be formed in a sequential stacked structure of a first inorganic insulation layer, an organic insulation layer, and a second inorganic insulation layer.

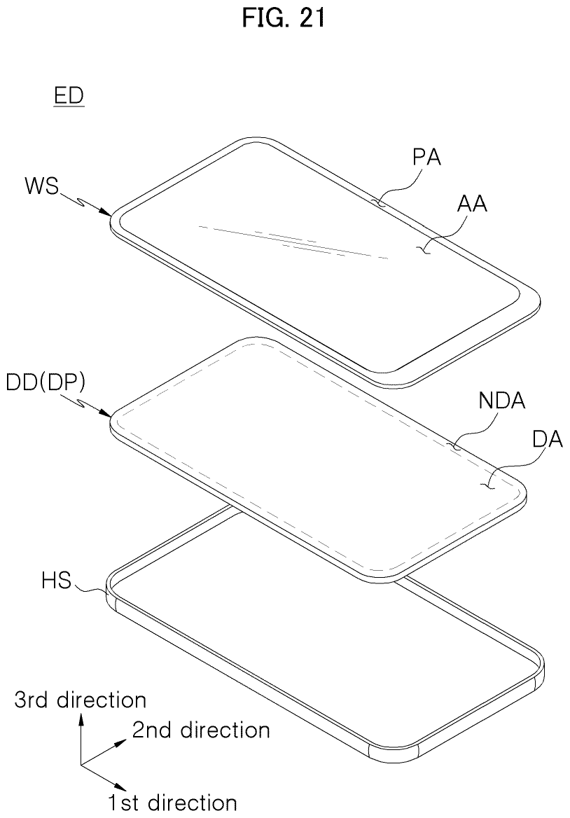

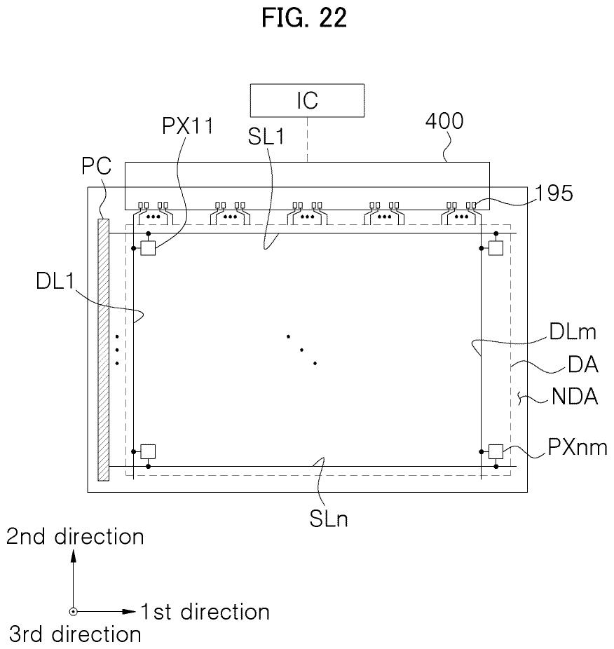

FIG. 21 is an exploded perspective view illustrating an electronic device according to embodiments. FIG. 22 is a schematic plan view illustrating arrangement of pixels of a display device included in an electronic device according to embodiments.

In FIGS. 21 and 22, a first direction and a second direction may refer to two directions parallel to a window structure WS and/or a display surface of the display panel DP, and perpendicular to each other. For example, the first direction may correspond to an X-direction (a row direction) of a display device DD or a display panel DP, and the second direction may correspond to a Y-direction (a column direction) of the display device DD or the display panel DP.

A third direction may be perpendicular to the first direction and the second direction. The third direction may correspond to a Z-direction (a thickness direction) of the display device DD or the display panel DP.

Referring to FIG. 21, an electronic device ED may include the window structure WS, a display device DD, and a housing HS. The display device DD may include the display panel DP including the above-described transistor elements and the light-emitting portion. The housing HS, the display device DD and the window structure WS may be sequentially stacked in the third direction.

The window structure WS may provide, e.g., an external display surface or a viewing surface recognized by a user, and may include a transparent material film. For example, the window structure WS may include glass (e.g., ultra-thin glass (UTG), a hard coating film, a plastic film, or the like).

An outer surface of the window structure WS may include an active area AA and a peripheral area PA. The active area AA may substantially display an image of the display device DD, and may provide a surface to which a user's touch/command is input. The peripheral area PA may substantially correspond to a bezel area of the electronic device ED.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

For example, a sensor structure for touch sensing or fingerprint sensing may be disposed in the display panel DP or between the window structure WS and the display panel DP.

The housing HS may serve as a frame structure or a rear housing of the display device DD or the electronic device ED. A cover panel may be disposed between the housing HS and the display panel DP. The housing HS or the cover panel may include a plate (for example, an SUS plate) that supports the display panel DP, a printed circuit board 400 (see FIG. 22), or the like. The housing HS or the cover panel may include an elastic body for absorbing shock of the display device DD.

Referring to FIG. 22, a plurality of pixels PX11 to PXnm may be arranged in the display area DA of the display panel DP.

According to embodiments, a pixel circuit including scan lines (or gate lines SL1 to SLn) forming first to nth rows, and data lines DL1 to DLm forming first to mth columns may be arranged on the base substrate 100 of the display device DD or the display panel DP. Each of the pixels PX11 to PXnm may be connected to a corresponding scan line among a plurality of scan lines SL1 to SLn and a corresponding data line among a plurality of data lines DL1 to DLm.

For example, the scan lines SL1 to SLn may be connected to the gate electrode included in the thin film transistor. The data lines DL1 to DLm may be connected to, e.g., a contact electrode (e.g., the first contact electrode CNT1 or the third contact electrode CNT2) provided as a source electrode.

Each of the pixels PX11 to PXnm may further include a pixel circuit including the transistor element and the light-emitting element as described above. The pixel circuit may further include wiring such as a power line, a ground line, or the like.

FIG. 22 illustrates that the data lines DL1 to DLm extend in the second direction and the scan lines SL1 to SLn extend in the first direction, but embodiments are not limited to the construction of FIG. 22.

A peripheral circuit PC may be disposed in the peripheral area PA of the electronic device ED or the non-display area NDA of the display device DD. For example, the peripheral circuit PC may include a gate driving circuit. The gate driving circuit may be integrated into the display panel DP through an oxide semiconductor gate (OSG) driving circuit process, an amorphous silicon gate (ASG) driving circuit process, or a polysilicon gate (PSG) driving circuit process.

The electronic device DD may further include the printed circuit board 400. Pads 195 of the pixel circuit (e.g., data lines) may be assembled on one side of the non-display area NDA. The printed circuit board 400 may be electrically connected to the pixel circuit through the pads 195. For example, the printed circuit board 400 may be electrically connected to the pads 195 by a heating-compression process using a conductive intermediate structure such as an anisotropic conductive film ACF.

The pads 195 and a driving circuit element IC may be electrically connected through the printed circuit board 400. The driving circuit element IC may include an integrated circuit chip. In some embodiments, the integrated circuit chip may be mounted on the printed circuit board 400 in the form of a chip-on-film (COF).

The driving circuit element IC may include a driving circuit of the display device DD and a driving circuit (for example, an application processor (AP) chip) of the electronic device ED. The driving circuit element IC may further include a circuit board such as a main board on which a chip including the driving circuit is mounted.

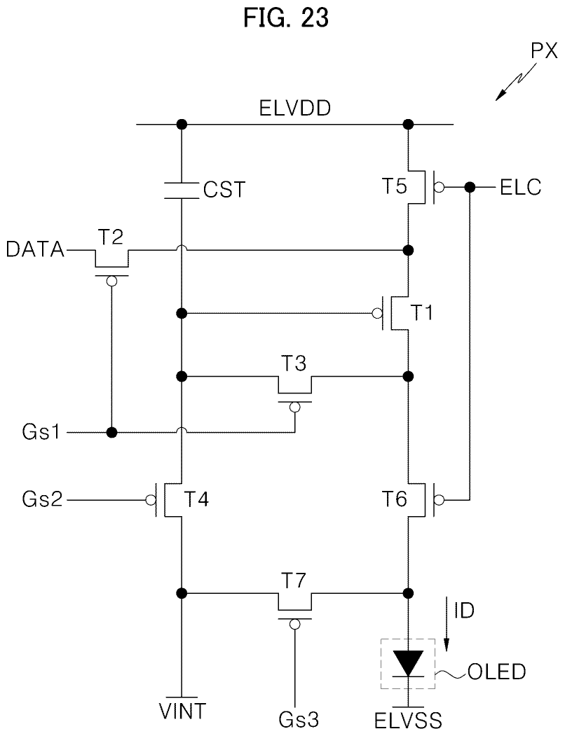

FIG. 23 is a pixel equivalent circuit diagram of a display device according to embodiments.

Referring to FIG. 23, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal and a second terminal. The gate terminal of the second transistor T2 may receive a first gate signal Gs1. The second transistor T2 may be turned on or turned off according to the first gate signal Gs1. The first terminal of the second transistor T2 may receive a data voltage DATA. The second transistor T2 may provide the data voltage DATA to the first terminal of the first transistor T1 according to the first gate signal Gs1. For example, the second transistor T2 may be referred to as a switching transistor.

The third transistor T3 may include a gate terminal, a first terminal and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal and a second terminal. The gate terminal may receive the emission control signal ELC. The first terminal may be connected to the first transistor T1. The second terminal may be connected to an organic light emitting diode OLED. The sixth transistor T6 may transfer the driving current ID to the organic light emitting diode OLED according to the emission control signal ELC.

The seventh transistor T7 may include a gate terminal, a first terminal and a second terminal. The gate terminal may receive a third gate signal Gs3. The first terminal may be connected to the organic light emitting diode OLED. The second terminal may receive the initialization voltage VINT. The seventh transistor T7 may initialize the organic light emitting diode OLED.

The storage capacitor CST may include a first terminal and a second terminal. The first terminal may receive the high-power supply voltage ELVDD. The second terminal may be connected to the gate terminal of the first transistor T1,

The organic light emitting diode OLED may include a first terminal and a second terminal. The first terminal may be connected to the sixth transistor T6. The second terminal may receive a low-power supply voltage ELVSS. The organic light emitting diode OLED may emit a light based on the driving current ID.

In some embodiments, the first transistor element TR1 including the first active layer ACT1 that may include the silicon-based semiconductor may be used as the first transistor T1. In some embodiments, the second transistor element TR2 including the second active layer ACT2 that may include the oxide semiconductor may be used as the second transistor T2.

In FIG. 23, a structure of 7T1C including seven thin film transistors and one storage capacitor CST in each pixel PX is illustrated, but the pixel structure of the display device disclosed herein is not limited thereto.

For example, each pixel PX may include two or more transistors, and may have a structure such as 2T1C, 5T1C, 6T1C, 5T2C, 6T2C, or the like.

The above-described display device DD may include a liquid crystal display (LCD) device, an organic light emitting diode (OLED) display device, a quantum dot light emitting diode (QLED) display device, or the like. According to embodiments, the display device DD may be an OLED display device including an organic emission layer.

For example, the electronic device ED to which the display device DD is applied may include a flat panel display, a curved display, a computer monitor, a medical monitor, a television, a billboard, an indoor or outdoor lighting, a signal lighting, a head-up display, a transparent display, a flexible display, a rollable display, a foldable display, a laser printer, a phone, a mobile phone, a tablet, a phablet, a personal digital assistant (PDA), a wearable device, a laptop computer, a digital camera, a camcorder, a viewfinder, a micro display, a 3D display, a virtual or augmented reality display, a vehicle, a video wall, a theater or a stadium screen, a phototherapy device, etc.

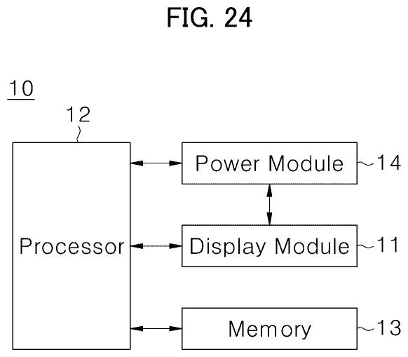

FIG. 24 is a block diagram of an electronic device in accordance with an embodiment.

Referring to FIG. 24, an electronic device 10 according to an embodiment may include a display module 11, a processor 12, a memory 13 and a power module (i.e., power supply) 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module (i.e., display panel) 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module (i.e., power supply circuit) such as a power adapter or a battery device, and a power conversion module (i.e., power conversion circuit) that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

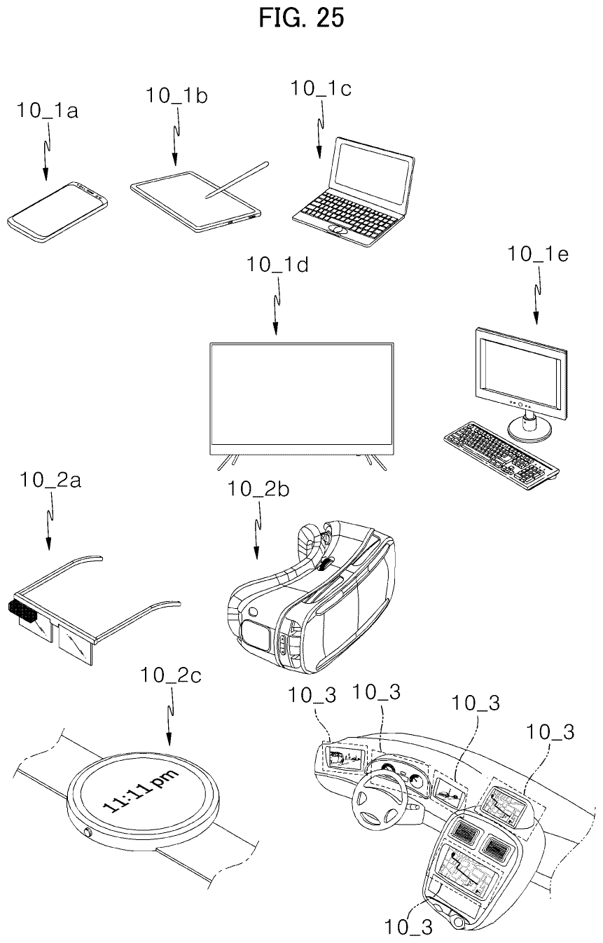

FIG. 25 is a schematic diagram of electronic devices in accordance with various embodiments.

Referring to FIG. 25, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a head-up display, a room mirror display, and the like. The electronic device may include a virtual reality glass or an augmented reality glass.

While aspects of embodiments have been particularly shown and described, it will be understood that various changes in form and details may be made therein without departing from the spirit and scope of the following claims.

What is claimed is:

1. A display device, comprising:
a base substrate;
an active layer on the base substrate, the active layer comprising a contact region and a channel region;
a gate electrode overlapping the channel region of the active layer;
a gate insulation layer between the active layer and the gate electrode;
an insulating interlayer on the gate electrode on the base substrate and having stepped surfaces and an inclined surface that connects the stepped surfaces;
a stopper layer on the insulating interlayer, the stopper layer exposing at least a portion of the inclined surface or having a thickness reduced on the inclined surface compared to a thickness on the stepped surfaces;
a contact electrode penetrating the insulating interlayer to be connected to the contact region of the active layer; and
a display element connected to the contact electrode.

2. The display device of claim 1, wherein the stopper layer comprises an amorphous carbon layer.

3. The display device of claim 1, wherein the stepped surfaces comprise a first stepped surface positioned over a top surface of the gate electrode and a second stepped surface at a height between the first stepped surface and the base substrate, and
wherein the stopper layer comprises a first portion on the first stepped surface and a second portion on the second stepped surface.

4. The display device of claim 3, wherein the first portion and the second portion are spaced apart by the inclined surface of the insulating interlayer.

5. The display device of claim 3, wherein an end portion of the first portion or the second portion extends onto the inclined surface.

6. The display device of claim 3, wherein the stopper layer comprises an inclined portion formed on the inclined surface of the insulating interlayer, and
wherein the inclined portion is thinner than each of the first portion and the second portion.

7. The display device of claim 3, wherein the first stepped surface and the second stepped surface are parallel to a top surface of the base substrate.

8. The display device of claim 1, wherein the contact electrode comprises a contact portion penetrating the insulating interlayer and a wiring portion on a top surface of the insulating interlayer, and
wherein the wiring portion contacts the stopper layer on one or more of the stepped surfaces.

9. The display device of claim 8, wherein the wiring portion contacts the inclined surface of the insulating interlayer.

10. The display device of claim 1, wherein the insulating interlayer comprises:
a first insulating interlayer covering the active layer and the gate electrode, the first insulating interlayer comprising silicon oxide; and
a second insulating interlayer on the first insulating interlayer, the second insulating interlayer comprising silicon nitride.

11. The display device of claim 10, wherein the active layer comprises an oxide semiconductor.

12. The display device of claim 1, wherein the gate electrode comprises a sequentially stacked structure of a first metal layer, a second metal layer, and a third metal layer.

13. The display device of claim 1, wherein the inclined surface of the insulating interlayer faces a side surface of the gate electrode.

14. A method of manufacturing a display device, comprising:
forming a first active layer on a base substrate;
forming a first gate insulation layer on the first active layer on the base substrate;
forming a first gate electrode overlapping the first active layer on the first gate insulation layer;
forming a second gate insulation layer on the first gate electrode on the first gate insulation layer;
forming a second active layer on the second gate insulation layer;
forming a third gate insulation layer on the second active layer;
forming a second gate electrode overlapping the second active layer on the third gate insulation layer;
forming an insulating interlayer on the second gate electrode, the insulating interlayer comprising stepped surfaces and an inclined surface that connects the stepped surfaces;
forming a stopper layer on the insulating interlayer;
performing an etchant treatment to at least partially remove a portion of the stopper layer on the inclined surface of the insulating interlayer;
forming contact electrodes penetrating the insulating interlayer to be connected to each of the first active layer and the second active layer; and
forming a display element connected to at least one of the contact electrodes.

15. The method of claim 14, further comprising forming a contact hole penetrating the stopper layer and the insulating interlayer, the contact hole partially exposing the first active layer before performing the etchant treatment,
wherein the etchant treatment comprises removing an etching residue in the contact hole.

16. The method of claim 15, wherein a portion of the stopper layer of the insulating interlayer remains on the stepped surfaces after the etchant treatment.

17. The method of claim 15, wherein the etchant treatment comprises a buffer oxide etchant (BOE) treatment.

18. The method of claim 14, wherein the first active layer comprises a silicon-based semiconductor and the second active layer comprises an oxide semiconductor.

19. An electronic device, comprising:
a display device;
a memory; and
a processor executing data included in the memory to control an operation of the display device, wherein the display device comprises:
a base substrate;
an active layer on the base substrate, the active layer comprising a contact region and a channel region;
a gate electrode overlapping the channel region of the active layer;
a gate insulation layer between the active layer and the gate electrode;
an insulating interlayer on the gate electrode on the base substrate and having stepped surfaces and an inclined surface connecting the stepped surfaces;
a stopper layer on the insulating interlayer, the stopper layer exposing at least a portion of the inclined surface or having a thickness reduced on the inclined surface compared to a thickness on the stepped surfaces;
a contact electrode penetrating the insulating interlayer to be connected to the contact region of the active layer; and
a display element connected to the contact electrode.

20. The electronic device of claim 19, wherein the electronic device forms at least one of a flat panel display, a curved display, a computer monitor, a medical monitor, a television, a billboard, an indoor or outdoor lighting, a signal lighting, a head-up display, a transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle, a video wall, a theater or stadium screen, or a phototherapy device.
